(19) United States
(12) Patent Application Publication
(10) Pub. No.: US 2014/0332053 A1
(43) Pub. Date: Nov. 13, 2014

(54) PROTECTIVE CIRCUIT FOR AN ELECTRICALLY FLOATING PHOTOVOLTAIC ARRAY

(71) Applicant: SOLAR SYSTEMS PTY LTD, Abbotsford, Victoria (AU)

(72) Inventor: Zhen Mu, Wantirna (AU)

(21) Appl. No.: 14/353,152

(22) PCT Filed: Oct. 21, 2012
(86) PCT No.: PCT/AU2012/001220

§ 371 Date: Apr. 21, 2014

Related U.S. Application Data
(60) Provisional application No. 61/549,757, filed on Oct. 21, 2011.

(51) Int. Cl. H02H 3/18; H02H 3/16; H01L 31/052; H02H 7/20

(52) U.S. Cl. CPC H02H 3/18; H02H 7/20; H02H 3/16; H01L 31/0522
USPC 136/246; 361/42

(57) ABSTRACT

A protective circuit for an electrically floating photovoltaic array including a plurality of strings, each string including one or more photovoltaic modules connected in series, the plurality of strings being connected in parallel to supply electrical power from the photovoltaic modules to a load. A first string of the plurality of strings further includes two diodes connected in series, with one or more of the photovoltaic modules connected in series between the two diodes, to prevent a harmful reverse cur rent through at least one photovoltaic module in the event of a multiple earth fault.

### FIELD OF THE INVENTION

The present invention relates generally to protective circuits for an electrically floating photovoltaic array that may prevent or limit damage to photovoltaic modules in the array that may occur during earth faults.

### BACKGROUND OF THE INVENTION

A typical photovoltaic cell is a semiconductor device that converts solar energy to electrical energy by the photovoltaic effect. Photons from sunlight having an energy that matches or exceeds the bandgap of the semiconductor are absorbed, knocking loose electrons that may then flow through an external current path to produce electricity. Multi junction solar cells have multiple layers of semiconductor materials with decreasing bandgaps. The upper layers absorb high energy photons and transmit lower energy photons to be absorbed by the lower layers. Multi junction cells (for example triple-junction cells) thus convert sunlight to electricity more efficiently than single junction cells.

As photovoltaic cells individually produce a low voltage and current, they are joined together in series or parallel to produce a photovoltaic module. To further increase the power output of a photovoltaic system, photovoltaic modules are often connected together to produce a photovoltaic array. A common photovoltaic array configuration is a multi-strings arrangement as shown in FIG. 1. The photovoltaic array 10 includes multiple photovoltaic modules 12 connected in series to form strings 14, 16, 18. A group of strings 14, 16, 18 are connected in parallel feeding into a power conditioning unit 20 such as an inverter.

The photovoltaic array may be implemented in different electrical arrangements as shown in FIG. 2: a floating and isolated PV array (FIG. 2a), an earthed and isolated PV array (FIG. 2b) and a floating PV array referenced to earth via a transformerless inverter (FIG. 2c). A major concern with these configurations is that under some fault conditions, unwanted harmful reverse current may flow through the PV modules and some segments of cable. This may occur if there is a single earth fault (for the FIGS. 2b and 2c arrangements) or two or more earth faults (for the FIG. 2a configuration) in the PV system. The reverse current may lead to overheating of the module, which may damage the module and may cause localised burn out or fires.

FIG. 3 shows an example of a reverse current pathway for a 3-strings floating PV array system under a two earth faults 21, 22 condition. The power output of the circuit 10 is reduced to zero under this two earth faults 21, 22 condition. The observations from a node analysis of this fault case are as follows:
Module PV3-4 is forward biased with a voltage that is larger than its open circuit voltage. Thus the module is operating in the second quadrant of its I-V characteristic (i.e. the current through module PV3-4 is negative and it is forced to dissipate the power delivered by PV strings 14 and 16).
As the voltage of strings 14 and 16 drops, their output current increases to approximately their short circuit value Isc. If standard test conditions are assumed, the reverse current through module PV3-4 is therefore approximately twice Isc.
The current of the section of a string cable that connects module PV3-4 with a negative bus bar is also twice Isc.
Module PV3-1, PV3-2 and PV3-3 output short-circuit current Isc.
The reverse current through PV module PV3-4 and through the segment of the string cable that connects it to the negative bus bar increases by approximately Isc for each additional parallel PV string in the circuit.

FIG. 4 shows a protection method used in a multi-string PV installation which employs over-current protection devices 24 such as dc fuses. The dc fuses 24 are added to both the positive and negative connection path for each PV string 14, 16, 18. This arrangement can limit the reverse current of affected PV modules to a certain degree under fault conditions.

FIG. 5 shows the PV array circuit with dc fuses 24 under the same two earth fault condition as shown in FIG. 3. FIG. 5a shows the circuit before, and FIG. 5b after, the fuse F3-2 breaks. With reference to FIG. 5a, when the earth faults 21, 22 occur, there is a period of time before the fuse F3-2 breaks where there is a reverse current being injected into module PV3-4.

If the in-line fuse F3-2 on the negative side of module PV3-4 is properly specified (normally 1.2×Isc) it will break, preventing a fault current (in this case 2×Isc) from continuously flowing through module PV3-4 and its associated cable segment if the earth faults 21, 22 persisted. The result of the fuse F3-2 breaking is shown in FIG. 5b. Module PV3-4 is taken out of the circuit 10, modules PV3-1, PV3-2 and PV3-3 are earthed and the remaining modules continue to operate normally.

The in-line fuses circuit limits the reverse current flow through the PV modules to a degree which is greater than Isc but less than a maximum reverse current permitted for the PV modules. This is sufficient to prevent damage to many silicon or thin film PV cells/modules but may not prevent damage to some newly developed PV cells/modules such as triple-junction solar cells. Due to technical complexity, the allowable reverse current rating for triple-junction PV cells is much lower than its Isc. In many cases, triple-junction PV cell manufacturers do not specify the reverse current limitation. Therefore, the in-line fuses arrangement may not be appropriate to protect these types of cells in the event of severe earth faults developed in the PV system.

It would be desirable to provide a protective circuit for an electrically floating photovoltaic array that addresses one or more of the limitations described above or provides an alternative to existing protective circuits.

The above discussion of background art is included to explain the context of the present invention. It is not to be taken as an admission that any of the documents or other material referred to was published, known or part of the common general knowledge at the priority date of any one of the claims of this specification.

### SUMMARY OF THE INVENTION

The present invention provides a protective circuit for an electrically floating photovoltaic array including a plurality of strings, each string including one or more photovoltaic modules connected in series, the plurality of strings being connected in parallel to supply electrical power from the photovoltaic modules to a load, wherein a first string of the plurality of strings further includes two diodes connected in series, with one or more of the photovoltaic modules connected in series between the two diodes, to prevent a harmful reverse current through at least one photovoltaic module in the event of a multiple earth fault with at least one of the earth faults occurring between the two diodes.

The protective circuit may eliminate harmful reverse current to photovoltaic modules between the two diodes under any earth fault condition, whether there is a single earth fault, two earth faults or more earth faults. Therefore, it may prevent damage caused by reverse current to PV cells/modules presently on the market, or developed in the future.

An electrically floating photovoltaic array is a photovoltaic array that is not earthed. For example, as shown in FIG. 2a, the PV array 28 may be connected to a DC-AC inverter 30 having a transformer. The transformer within the inverter 30 isolates the PV array 28 from the AC side 32. The electrically floating photovoltaic array may alternatively be connected to a transformerless inverter as shown in FIG. 2c. A floating PV array with a transformerless inverter installation is becoming popular as it takes advantage of the floating/ungrounded earth PV system configuration to reduce the cost of the inverter.

For an ungrounded (floating) PV system, a grid-connected inverter can be relatively simple compared to what is required in a grounded PV system. With a grounded circuit conductor from the PV array and a grounded circuit conductor in the ac inverter output circuit, it is not possible to use a direct switching device because the switch would be shorted as it tried to reverse the polarity of the dc circuit into an ac signal. A transformer is required to isolate the grounded dc circuits from the grounded ac circuits in this situation. The transformer is usually a heavy, costly and bulky device that decreases efficiency, increases the size, and increases the shipping costs of the inverter. In a floating PV system, the inverter can work with and without a transformer.

A multiple earth fault is to be understood to mean two or more earth faults in the circuit, causing two or more parts of the circuit to be earthed at the same time. As described above, a multiple earth fault may cause unwanted harmful reverse current in an unprotected floating PV system.

One of the two diodes of the first string may be connected at one end of the first string and the other of the two diodes of the first string may be connected at the other end of the first string. This means that all of the photovoltaic modules on the first string are between the two diodes, and protected from harmful reverse current flow. Alternatively, the diodes may be located so as to protect only a subset of the number of photovoltaic modules on the first string. For example, the diodes may be positioned on either side of modules that are particularly expensive or sensitive to reverse current flow.

In an embodiment, each string of the plurality of strings includes two diodes connected in series, with one or more of the photovoltaic modules of the respective string connected in series between the two diodes. By providing diodes on each string, the photovoltaic modules between the two diodes on each string are also protected against damage in the event of a multiple earth fault. Again, one of the two diodes of each string may be connected at one end of the respective string and the other of the two diodes of each string may be connected at the other end of the respective string. In this embodiment, all of the photovoltaic modules are protected against harmful reverse currents in the event of a multiple earth fault anywhere in the protective circuit.

An analysis of the circuit may be conducted before deciding on placement of the diodes, to determine segments of the circuit where earth faults are likely to occur, and the diodes may accordingly be placed in series on either side of these segments. Each diode may be positioned adjacent to an output terminal (positive or negative) of a photovoltaic module. For example, a diode may be located as close as possible to the output terminal. Locating the diode as close as possible to the output terminal may provide greater protection to PV cells in the module. The paired diodes arrangement may protect PV cells or modules which are physically connected between the two diodes against potential multi-earth faults.

The term “photovoltaic module” is to be understood to include any photovoltaic module, photovoltaic device, photovoltaic cell or photovoltaic panel. A “plurality” of strings of one or more photovoltaic modules is to be taken to mean two or more strings. In one example, the photovoltaic modules in the photovoltaic array may each include one or more photovoltaic cells for converting photons to electrical energy. The photovoltaic cells may be single or multi junction cells, and may be electrically connected in series, parallel or a combination of series and parallel, as would be understood by the skilled addressee. The cells may be arranged in a two dimensional array, in abutting relationship on a curved substrate, on a multi-surface substrate such as a cube or in a linear dense array of cells.

Any type of diode may be used in the protective circuit, and the diodes used need not be the same. For example, a different type of diode may be used at either end of a string, or on one string compared to another string. Examples of diodes that may be used include standard rectifier diodes, fast-recovery or ultra-fast recovery diodes.

When a diode operates in its reverse blocking region, it allows a very small leakage current through it continuously. The value of the leakage current to a diode is normally in the order of tens to hundreds uA range which does no harm to the PV modules. Thus, although the diodes allow a small leakage current through the PV modules, it will be understood that the diodes prevent a “harmful reverse current” through the modules.

In an embodiment, the diodes may be fast or ultrafast recovery diodes. If fast or ultrafast recovery diodes are used, the peak reverse current and duration of a transient period from the forward conducting state to the reverse blocking state may be controlled to be within an acceptable range as defined by a PV cell/module specification.

By contrast, in a dc fuses circuit, even though a dc fuse breaks the reverse current pathway when there is persistent over-current, there is still a period of time before the fuse breaks where there is a reverse current being injected into some PV modules. The duration of the time depends on the selected fuse characteristic and the magnitude of fault current. The fault current may be extremely high if a large number of strings are connected, as the maximum fault current passing through the affected PV modules is the number of strings n×Isc. This may result in permanent damage to the PV modules as they operate outside their design specification, even if the duration of the fault current is in the order of tens to hundreds of milliseconds. The peak reverse current in the dc fuses arrangement is largely determined by the number of PV strings and environment condition when the earth faults occur.

Also, as a fuse operates in both directions, its rating must be above the maximum forward current of the photovoltaic cell, so that the fuse does not break when the photovoltaic modules are operating normally. Diodes do not have this limitation, enabling them to restrict reverse current to a finer degree than fuses.

The protection mechanism of the present invention is based on the reverse blocking nature of the diodes when the potential of the cathode is higher than the anode. No additional external intervention is required to protect the PV modules. The protection function may be repeatable without sacrificing any components, unlike the fuse arrangement where a fuse breaks to protect the PV modules, and must be replaced.

The present invention also provides advantages over an arrangement where a single blocking diode is placed in series with a PV string. In this arrangement, PV modules on the string are protected in the event of a single earth fault, but not if there are two or more earth faults.

The load to which the strings of the protective circuit are connected in parallel may include an inverter for converting power from the photovoltaic modules from DC to AC. Each diode may be connected between the inverter and a photovoltaic module. In one example, the diodes may be located in the inverter.

The protective circuit may be used in a concentrated solar power system. A concentrated solar power system includes a receiver and a concentrator. The concentrator reflects light incident on a relatively large surface area to a relatively small surface area of the receiver. For example, the concentrator may be a dish reflector that includes a parabolic array of mirrors that reflect light towards the receiver or a heliostat reflector that includes a field of independently movable flat mirrors. The receiver may include a plurality of strings of photovoltaic power modules, each module including a dense array of photovoltaic cells for converting incident light into electrical energy. The receiver may also include an electrical circuit for transferring the electrical energy output of the photovoltaic cells and an inverter to convert the DC output of the photovoltaic cells to AC.

Accordingly, the present invention also provides a receiver including a protective circuit according to any one of the embodiments described above.

The present invention further provides a solar power generator including a photovoltaic receiver for converting concentrated solar radiation into electrical energy, and a concentrator for concentrating the solar radiation on the photovoltaic receiver, the photovoltaic receiver including a protective circuit according to any one of the embodiments described above.

The present invention also provides a method of generating electric power including operating the solar power generator.

It will be appreciated that the protective circuit is not limited to use in a concentrated solar power system, where a concentrator reflects light towards the module. For example, the module may receive direct sunlight (single concentration) or low concentration light. The protective circuit may be used in any form of solar power system.

### BRIEF DESCRIPTION OF THE DRAWINGS

Embodiments of the present invention will now be described, by way of example only, with reference to the accompanying drawings. It is to be understood that the particularity of the drawings does not supersede the generality of the preceding description of the invention.

FIG. 1 is a schematic plan view of a multi string photovoltaic array.

FIG. 2 is a schematic plan view of a floating and isolated PV array (2a), an earthed and isolated PV array (2b) and a floating PV array referenced to earth via a transformerless inverter (2c).

FIG. 3 is a schematic plan view of a floating PV array with two earth faults.

FIG. 4 is a schematic plan view of a multi string PV array with dc fuses.

FIG. 5 is a schematic plan view of the multi string PV array with dc fuses of FIG. 4 with the earth fault condition of FIG. 3 showing the array before (5a) and after (5b) the fuse breaks.

FIG. 6a is a schematic plan view of a protective circuit according to an embodiment of the invention.

FIG. 6b is a graph of the current-voltage characteristic of a diode.

FIGS. 7a-7d are schematic plan views of the protective circuit of FIG. 6a under four different two earth fault conditions.

FIG. 8 is a front view of a receiver in which the protective circuit of FIG. 6 may be deployed.

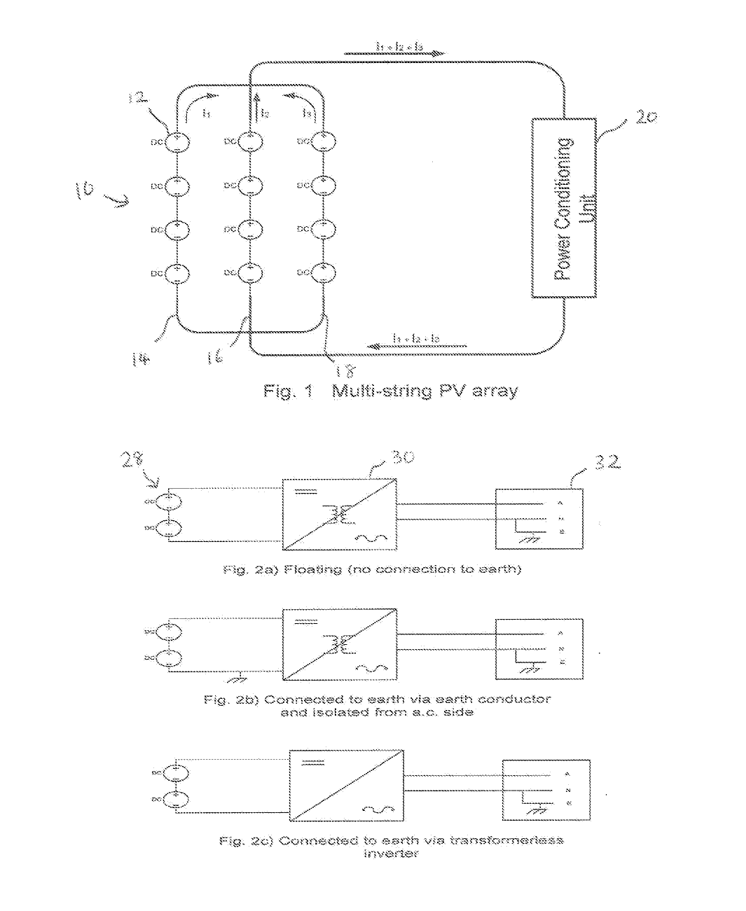

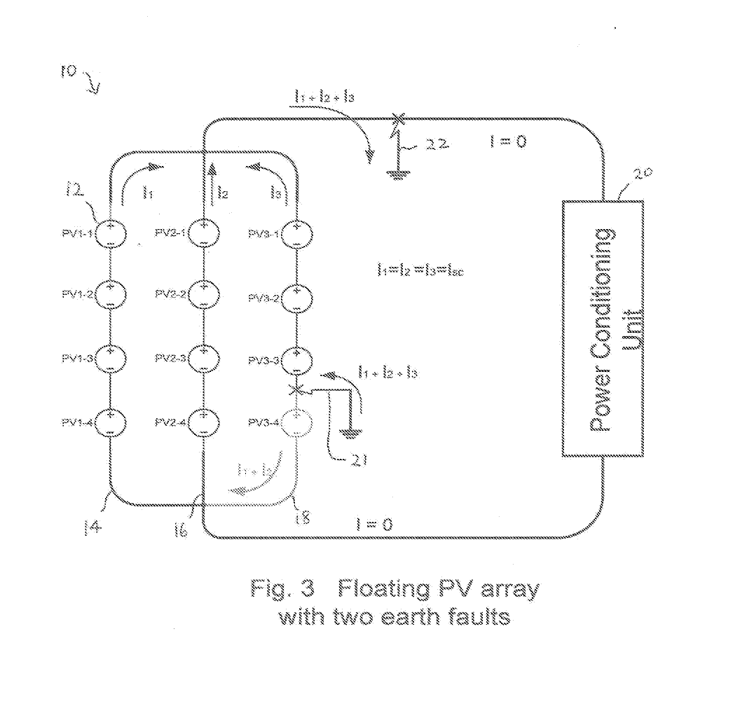

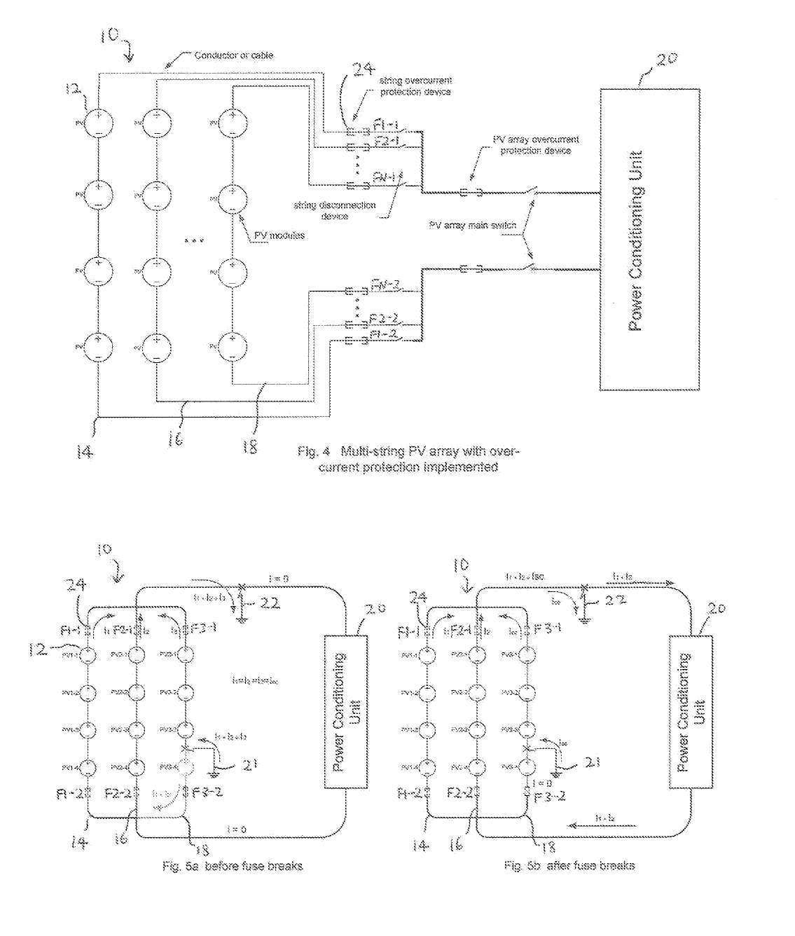

### DETAILED DESCRIPTION

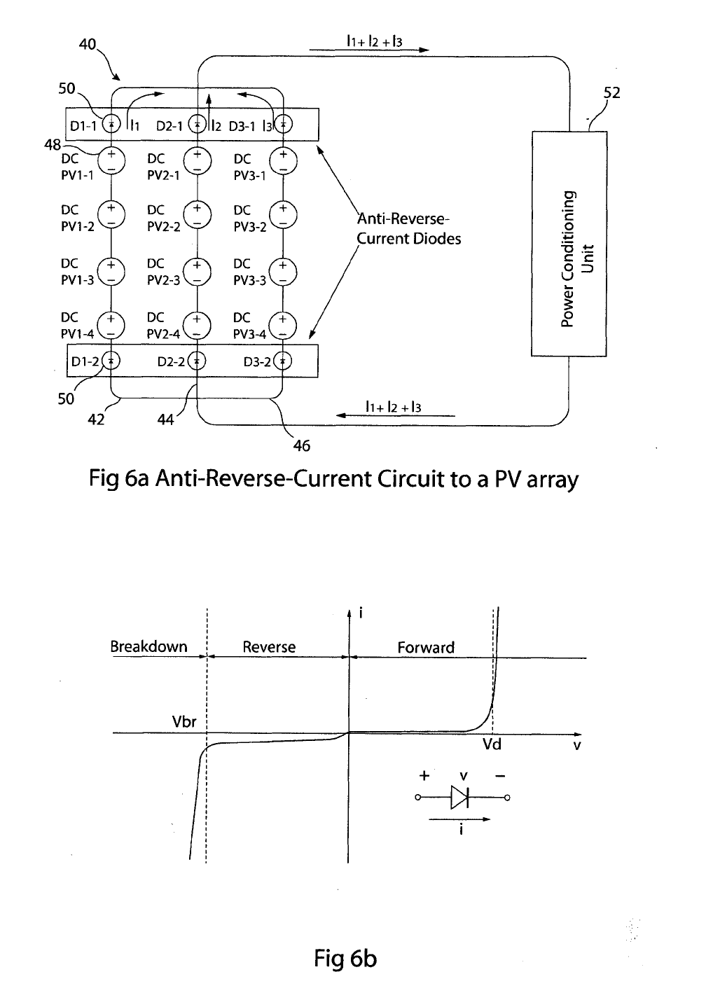

A protective circuit 40 according to an embodiment of the invention is shown in FIG. 6a. The protective circuit 40 is for protecting PV modules of an electrically floating photovoltaic array. The circuit 40 is therefore not earthed.

The protective circuit 40 shown in FIG. 6a includes three strings 42, 44, 46, each string including four photovoltaic modules 48 connected in series. The strings 42, 44, 46 are connected in parallel to supply electrical power from the photovoltaic modules 48 to a load 52. Each string 42, 44, 46 includes two diodes 50 connected in series, with one of the two diodes 50 connected at one end of the respective string 42, 44, 46 and the other of the two diodes 50 connected at the other end of the respective string 42, 44, 46. In this example the diodes 50 are located adjacent to the PV module 48 output terminals (positive and negative side), and are positioned as close to the terminals as possible.

Although FIG. 6a shows a circuit with 3 strings, each having 4 photovoltaic modules, this is for illustrative purposes only. In a more realistic example, the circuit may include a dense array of 64 modules of 36 photovoltaic cells arranged in series in a 6 cell by 6 cell array. The 64 modules may be arranged in groups of 4 series connected modules that are connected in parallel. Thus, the protective circuit may include 16 strings, each string including 144 photovoltaic cells. 32 diodes, one at either end of each string, could be used to protect all 2304 cells in the array. It will be appreciated that different numbers of cells and modules and other combinations of series and parallel connections are possible. The protective circuit 40 may include any number of strings, each string including any number of photovoltaic modules.

The load 52 in this example is a DC-AC inverter, which in turn is connected to an electricity grid or distribution system. Each diode 50 in this example is a fast recovery diode, connected between the inverter 52 and a photovoltaic module 48.

The diode 50 may be a semiconductor device which includes a positive P-type side and a negative N-type side. The P and N regions are formed by doping a semiconductor, for example silicon, with Group III and V elements respectively. The boundary between the P and N regions is called the PN junction. The diode 50 enables current flow from the N-type side (cathode) to the P-type side (anode) of the diode, but prevents conduction from the P-type side to the N-type side. A voltage current characteristic of the diode 50 is shown in FIG. 6b. When there is a positive voltage potential difference between the anode and cathode, the diode 50 blocks current. The diodes 50 are preferably fast- or ultra-fast recovery diodes.

In the event of a multiple earth fault, the diodes 50 block harmful reverse current through affected PV modules 48. Some PV modules 48 may be earthed and the remaining PV modules 48 may continue to operate safely, but with reduced power output. Thus the circuit 40 may continue operating until the fault is detected and fixed at a later time.

The protective circuit 40 may be used in conjunction with an earth fault detection measure to provide comprehensive earth fault protection to the array of photovoltaic modules 48. For example, a residual current detector (RCD) may detect earth leakage current or the inverter 52 may have a built in earth fault detection mechanism. The fault may be detected in some cases as loss of the string 42, 44, 46 current.

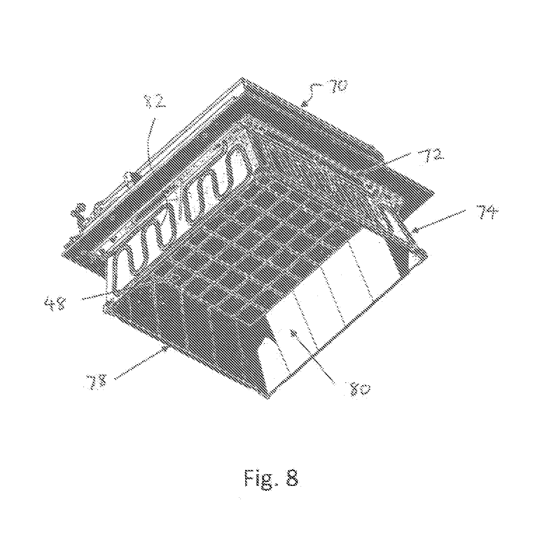

With reference to FIG. 8, the circuit 40 may be part of a receiver 70 for use in a concentrated solar power system. The receiver 70 has a generally box-like structure. The modules 48 are mounted on a lower wall 72 of the receiver 70. The receiver 70 also includes a solar flux modifier 74, which extends from the lower wall 72 of the box-like structure. The solar flux modifier 74 includes four panels 78 that extend from the lower wall 72 and converge toward each other. The solar flux modifier 74 also includes reflective surfaces 80 on the inwardly facing sides of the panels 78, for directing light onto the cells. The channels 82 on the flux modifier 74 form part of a coolant circuit for cooling the receiver 70. The diodes 50 are mounted on the back of receiver. The cooling fluid for cooling the PV modules may also provide heat dissipation to the diodes 50.

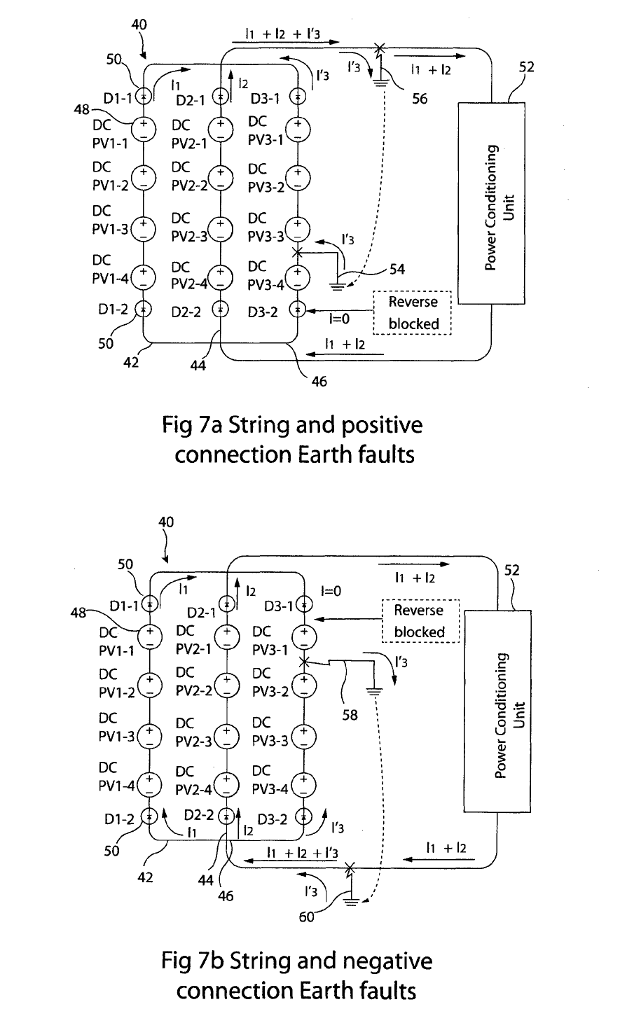

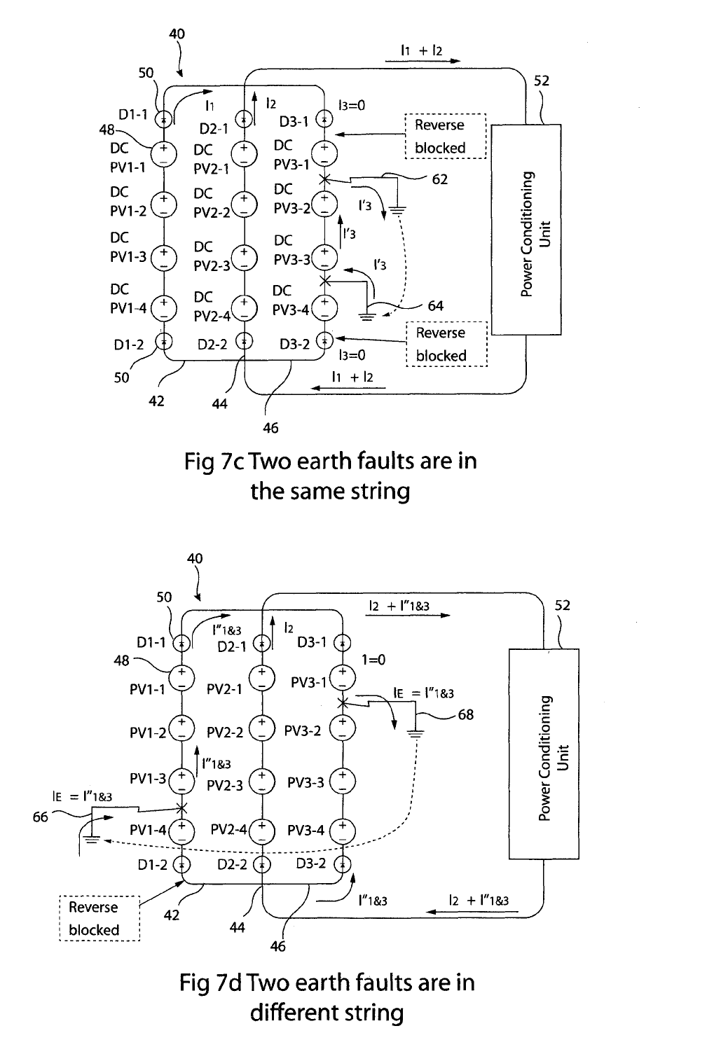

To better understand the operation of the protective circuit 40, FIGS. 7a to 7d show the protective circuit 40 under four different two earth fault conditions as will be described below.

In FIG. 7a, there is an earth fault 54 on string 46 and an earth fault 56 between the positive side of the array of PV modules 48 and the inverter 52. The earth faults 54 and 56 short circuit modules PV3-1, PV3-2 and PV3-3, so that they are no longer contributing to the overall power. Diode D3-2 prevents a harmful reverse current through module PV3-4, which is open circuited. Modules PV1-1, PV1-2, PV1-3, PV1-4, PV2-1, PV2-2, PV2-3 and PV2-4 continue to operate normally.

In FIG. 7b, there is an earth fault 58 on string 46 and an earth fault 60 between the negative side of the array of PV modules 48 and the inverter 52. The earth faults 58 and 60 short circuit modules PV3-2, PV3-3 and PV3-4, so that they are no longer contributing to the overall power. Diode D3-1 prevents a harmful reverse current through module PV3-1, which is open circuited. Modules PV1-1, PV1-2, PV1-3, PV1-4, PV2-1, PV2-2, PV2-3 and PV2-4 continue to operate normally.

In FIG. 7c, there are two earth faults 62 and 64 on string 46. The earth faults 62 and 64 short circuit modules PV3-2 and PV3-3, so that they are no longer contributing to the overall power. Diode D3-1 prevents a harmful reverse current through module PV3-1 and diode D3-2 prevents a harmful reverse current through module PV3-4. These modules are thus open circuited. Modules PV1-1, PV1-2, PV1-3, PV1-4, PV2-1, PV2-2, PV2-3 and PV2-4 continue to operate normally.

In FIG. 7d, there is an earth fault 66 on string 42 and an earth fault 68 on string 46. Diode D3-1 prevents a harmful reverse current through module PV3-1 and diode D1-2 prevents a harmful reverse current through module PV1-4. These modules are thus open circuited. The earth faults 66 and 68 do not short circuit any modules 48 as current is able to flow via the path through modules PV3-4, PV3-3, PV3-2 and then via earth to PV1-3, PV1-2 and PV1-1. Modules PV2-1, PV2-2, PV2-3 and PV2-4 continue to operate normally.

Observations from a node analysis of the above fault cases are as follows:
One or more of the diodes 50 act as blocking diodes to prevent reverse current flowing through PV modules 48 under fault conditions.
The protection function is passive and is based on the characteristic of diodes.
Depending on the fault condition, affected PV modules operate at open-circuit voltage or short-circuit conditions.
In a worst case, the diodes 50 need to be able to block a current path as high as 2 x Voc. For example, if two faults developed on two strings with one just above the bottom diode on one string and other located below the top diode of another string, it is possible that one of diodes may see 2 x Voc.
The maximum reverse current to affected PV modules is equal to the leakage current of the selected diodes (which is at the uA level, and less than 1 mA even in the worst case). This reverse current is not harmful to the PV modules.
The PV array system may still generate electrical power safely with reduced capacity.
Only those strings with earth faults in them are affected, the other strings may continue to operate without any disruption.

The protective circuit 40 may thus prevent harmful reverse current from passing through any PV module 48 in the event of multiple earth faults. All PV modules may continue operating in their safe range in the event of earth faults (in the first quadrant of their I-V characteristic).

It is to be understood that various alterations, additions and/or modifications may be made to the parts previously described without departing from the ambit of the present invention, and that, in the light of the above teachings, the present invention may be implemented in a variety of manners as would be understood by the skilled person.

1. A protective circuit for an electrically floating photovoltaic array including
a plurality of strings, each string including one or more photovoltaic modules connected in series,
the plurality of strings being connected in parallel to supply electrical power from the photovoltaic modules to a load,
wherein a first string of the plurality of strings further includes two diodes connected in series, with one or more of the photovoltaic modules connected in series between the two diodes, to prevent a harmful reverse current through at least one photovoltaic module in the event of a multiple earth fault with at least one of the earth faults occurring between the two diodes.

2. A protective circuit as claimed in claim 1,
wherein one of the two diodes of the first string is connected at one end of the first string and the other of the two diodes of the first string is connected at the other end of the first string.

3. A protective circuit as claimed in claim 1, wherein each string of the plurality of strings includes two diodes connected in series, with one or more of the photovoltaic modules of the respective string connected in series between the two diodes.

4. A protective circuit as claimed in claim 3,
wherein one of the two diodes of each string is connected at one end of the respective string and the other of the two diodes of each string is connected at the other end of the respective string.

5. A protective circuit as claimed in claim 1, wherein each diode is positioned adjacent to an output terminal of a photovoltaic module.

6. A protective circuit as claimed in claim 1, wherein each photovoltaic module includes a plurality of multijunction photovoltaic cells.

7. A protective circuit as claimed in claim 1, wherein each diode is a fast recovery diode.

8. A protective circuit as claimed in claim 1, wherein the load includes an inverter connected in parallel with the strings for converting power from the photovoltaic modules from DC to AC.

9. A protective circuit as claimed in claim 8, wherein each diode is connected between the inverter and a photovoltaic module.

10. A photovoltaic receiver including a protective circuit as claimed in claim 1.

11. A solar power generator including:
a photovoltaic receiver for converting concentrated solar radiation into electrical energy, and
a concentrator for concentrating the solar radiation on the photovoltaic receiver,
the photovoltaic receiver including a protective circuit as claimed in claim 1.

12. A method of generating electric power including operating the solar power generator of claim 11.

13. A protective circuit as claimed in claim 2, wherein each string of the plurality of strings includes two diodes connected in series, with one or more of the photovoltaic modules of the respective string connected in series between the two diodes.

14. A protective circuit as claimed in claim 13,
wherein one of the two diodes of each string is connected at one end of the respective string and the other of the two diodes of each string is connected at the other end of the respective string.

15. A protective circuit as claimed in claim 14, wherein each diode is positioned adjacent to an output terminal of a photovoltaic module.

16. A protective circuit as claimed in claim 15, wherein each photovoltaic module includes a plurality of multijunction photovoltaic cells

17. A protective circuit as claimed in claim 16, wherein each diode is a fast recovery diode.

18. A protective circuit as claimed in claim 17, wherein the load includes an inverter connected in parallel with the strings for converting power from the photovoltaic modules from DC to AC.

19. A protective circuit for an electrically floating photovoltaic array including
a plurality of strings, each string including one or more photovoltaic modules connected in series, each photovoltaic module including a plurality of multijunction photovoltaic cells,
the plurality of strings being connected in parallel to supply electrical power from the photovoltaic modules to a load,
wherein each string of the plurality of strings further includes two fast recovery diodes, such that a first diode of a string is connected at one end of the respective string and the other of the two diodes of each string is connected at the other end of the respective string with the one or more of the photovoltaic modules of the respective string connected in series between the two diodes, and
wherein in the event of a multiple earth fault with at least one of the earth faults occurring between the two diodes of a respective string, one of the diodes of that string is biased to prevent a harmful reverse current through a circuit path including at least one photovoltaic module and the earth fault occurring between the two diodes, whilst the other of said diodes is biased to allow operation of least one other photovoltaic module.
